(19) United States
(12) Patent Application Publication
(10) Pub. No.: US 2026/0165010 A1
(43) Pub. Date: Jun. 11, 2026

(54) DISPLAY DEVICE

(71) Applicant: LG Display Co., Ltd., Seoul (KR)

(72) Inventors: Dong-Ryul JUNG, Gyeonggi-do (KR); Ji-Seok YANG, Gyeonggi-do (KR); Je-Beom PARK, Gyeonggi-do (KR)

(21) Appl. No.: 19/286,893

(22) Filed: Jul. 31, 2025

(30) Foreign Application Priority Data
Dec. 11, 2024 (KR) 10-2024-0183774

(51) Int. Cl. H10K 59/80; H10K 59/122; H10K 59/38

(52) U.S. Cl. CPC H10K 59/8792; H10K 59/122; H10K 59/38

(57) ABSTRACT

A display device includes a substrate including a pixel region; a light emitting diode corresponding to the pixel region and disposed on the substrate; a light-shielding bank corresponding to a boundary of the pixel region and disposed on the substrate; a black matrix corresponding to the light-shielding bank and disposed on the light-shielding bank; and a color filter layer corresponding to the light emitting diode and disposed on the light emitting diode, wherein the color filter layer includes a first color filter pattern including an inclined side surface and a second color filter pattern on the first color filter pattern, and wherein the first color filter pattern has a first refractive index, and the second color filter pattern has a second refractive index being greater than the first refractive index.

### CROSS-REFERENCE TO RELATED APPLICATIONS

Pursuant to 35 U.S.C. § 119(a), this present application claims the benefit of an earlier filing date and right of priority to Korean Patent Application No. 10-2024-0183774 filed in the Republic of Korea on Dec. 11, 2024, the contents of which are hereby incorporated by reference in their entirety.

### TECHNICAL FIELD

The present disclosure relates to a display device.

### BACKGROUND

Recently, there has been increased demand for flat panel display devices that occupy less space. Among the flat panel display devices, a technology of an organic light emitting display device and an inorganic light emitting display device is rapidly developed.

For example, in the organic light emitting display device, holes from an anode and electrons from a cathode are combined to generate an exciton in an organic light emitting layer, and the exciton is transformed from an excited state to a ground state. As a result, the light is emitted from the organic light emitting display device.

### SUMMARY

An aspect of the present disclosure is a display device comprising a substrate including a pixel region; a light emitting diode corresponding to the pixel region and disposed on the substrate; a light-shielding bank corresponding to a boundary of the pixel region and disposed on the substrate; a black matrix corresponding to the light-shielding bank and disposed on the light-shielding bank; and a color filter layer corresponding to the light emitting diode and disposed on the light emitting diode, wherein the color filter layer includes a first color filter pattern including an inclined side surface and a second color filter pattern on the first color filter pattern, and wherein the first color filter pattern has a first refractive index, and the second color filter pattern has a second refractive index being greater than the first refractive index.

It is to be understood that both the foregoing general description and the following detailed description are exemplary and explanatory and are intended to further explain the present disclosure as claimed.

### BRIEF DESCRIPTION OF THE DRAWINGS

The accompanying drawings, which are included to provide a further understanding of the present disclosure and are incorporated in and constitute a part of this specification, illustrate implementations of the present disclosure and together with the description serve to explain the principles of the present disclosure.

FIG. 1 is a schematic view illustrating an organic light emitting display device of the present disclosure.

FIG. 2 is a schematic cross-sectional view illustrating an organic light emitting display device according to a first implementation of the present disclosure.

FIG. 3 is a schematic cross-sectional view illustrating an arrangement of a light-shielding bank and a black matrix in organic light emitting display device according to another implementation of the present disclosure.

FIG. 4 is a schematic cross-sectional view for explaining a decrease of an ambient light reflection in the organic light emitting display device according to the first implementation of the present disclosure.

FIG. 5 is a schematic cross-sectional view illustrating an organic light emitting display device according to a second implementation of the present disclosure.

FIG. 6 is a schematic plane view illustrating a color filter layer in organic light emitting display device according to another implementation of the present disclosure.

FIG. 7 is a schematic cross-sectional view illustrating an organic light emitting display device according to a third implementation of the present disclosure.

FIG. 8 is a schematic plane view illustrating an organic light emitting display device according to a fourth implementation of the present disclosure.

FIG. 9 is a schematic cross-sectional view taken along the line Xa-Xb in FIG. 8.

### DETAILED DESCRIPTION

Disclosed herein are implementations related to a display device, and more specifically, to a display device capable of providing high quality images by reducing ambient light reflection and brightness degradation.

Unlike a liquid crystal display device, an organic light emitting display device does not require a polarization plate. However, in the organic light emitting display device without a polarization plate, an image quality is decreased by an ambient light reflection. Accordingly, in some scenarios an organic light emitting display device may include a polarization plate at an image-display side to minimize ambient light reflection.

In the organic light emitting display device with the polarization plate, however, brightness is decreased by the polarization plate.

The present disclosure is directed to a display device that substantially obviates one or more of the problems associated with the limitations and disadvantages of the related conventional art.

An object of the present disclosure is to provide a display device being capable of reducing ambient light reflection and brightness degradation.

Additional features and advantages of the present disclosure are set forth in the description which follows, and will be apparent from the description, or evident by practice of the present disclosure. The objectives and other advantages of the present disclosure are realized and attained by the features described herein as well as in the appended drawings.

Reference will now be made in detail to aspects of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When ‘including’, ‘having’, ‘consisting’, and the like are used in this specification, other parts may be added unless ‘only’ is used. When a component is expressed in the singular, cases including the plural are included unless specific statement is described.

The expression “at least one of a, b, and c” described throughout the specification can encompass ‘a alone’, ‘b alone’, ‘c alone’, ‘a and b’, ‘a and c’, ‘b and c’, or ‘all of a, b, and c’. The advantages and features of the present invention, and the methods for achieving them, will become apparent by referring to the implementations described in detail below together with the accompanying drawings.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts may be disposed between the two parts unless a more limiting term, such as “just” or “direct(ly)” is used.

In describing a time relationship, for example, when the temporal order is described as, for example, “after,” “subsequent,” “next,” and “before,” a case that is not continuous may be included unless a more limiting term, such as “just,” “immediate(ly),” or “direct(ly)” is used.

The area, length, or thickness of each component described in the specification is illustrated for convenience of explanation, and the present invention is not necessarily limited to the area and thickness of the illustrated component.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various aspects of the present disclosure may be partially or overall coupled to or combined with each other, and may be variously inter-operated with each other and driven technically as those skilled in the art can sufficiently understand. The aspects of the present disclosure may be carried out independently from each other, or may be carried out together in co-dependent relationship.

Without specific description, a transistor constituting the pixel circuit of the present disclosure may include at least one of an oxide thin film transistor (Oxide TFT), an amorphous silicon TFT (a-Si TFT), and a low temperature poly silicon (LTPS) TFT.

The following implementations are described with reference to organic light emitting display devices. However, the implementation of the present disclosure is not limited to organic light emitting display devices. For example, a display device according to an implementation of the present disclosure may be an organic light emitting display device using an organic light emitting material, an inorganic light emitting display device using an inorganic light emitting material such as a quantum dot or a micro-LED display device using a micro-LED.

Reference will now be made in detail to some of the examples and preferred implementations, which are illustrated in the accompanying drawings.

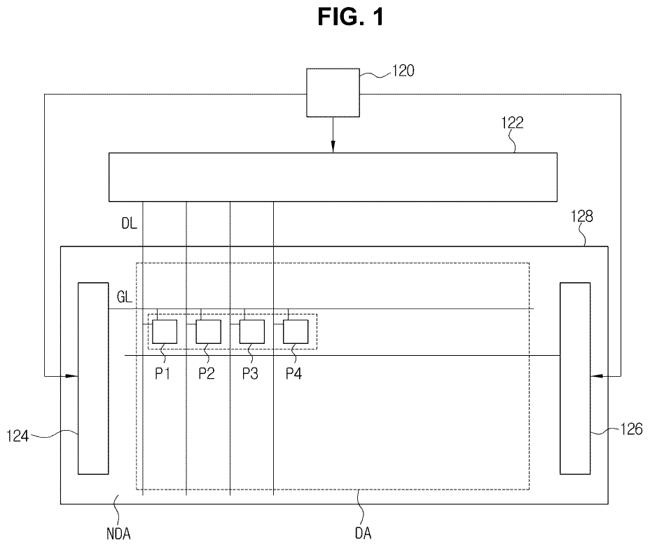

FIG. 1 is a schematic view illustrating an organic light emitting display device of the present disclosure.

As shown in FIG. 1, a display device 110 according to an implementation of the present disclosure includes a timing controlling unit 120 (e.g., a circuit), a data driving unit 122 (e.g., a circuit), first and second gate driving units 124 and 126 (e.g., circuits) and a display panel 128.

The timing controlling unit 120 generates an image data RGB, a data control signal and a gate control signal using an image signal and a plurality of timing signals including a data enable signal, a horizontal synchronization signal, a vertical synchronization signal and a clock signal transmitted from an external system. The timing controlling unit 120 transmits the image data and the data control signal to the data driving unit 122, and transmits the gate control signal to the first and second gate driving units 124 and 126.

The data driving unit 122 generates a data signal (a data voltage) using the image data and the data control signal transmitted from the timing controlling unit 120 and transmits the data signal to a data line DL of the display panel 128.

The first and second gate driving units 124 and 126 generate a gate signal (a gate voltage) using the gate control signal transmitted from the timing controlling unit 120 and applies the gate signal to a gate line GL of the display panel 128.

The first and second gate driving units 124 and 126 may have a gate in panel (GIP) type to be formed in a non-display area NDA of a substrate of the display panel 128 having the gate line GL, the data line DL and a pixel P.

Although the first and second gate driving units 124 and 126 are disposed in both side portions of the display panel 128 in the implementation of FIG. 1, one gate driving unit may be disposed in one side portion of the display panel 128 in another implementation.

The display panel 128 includes a display area DA at a central portion thereof and a non-display area NDA surrounding the display area DA. The display panel 128 displays an image using the gate signal and the data signal.

In the display panel 128, the gate line GL and the data line DL cross each other to define first to fourth pixel regions P1, P2, P3 and P4. For example, the first to fourth pixel region P1 to P4 may be red, green, blue and white pixel regions, respectively.

In each of the first to fourth pixel regions P1 to P4, a switching TFT, a driving TFT, a sensing TFT, a storage capacitor and a light emitting diode D may be disposed.

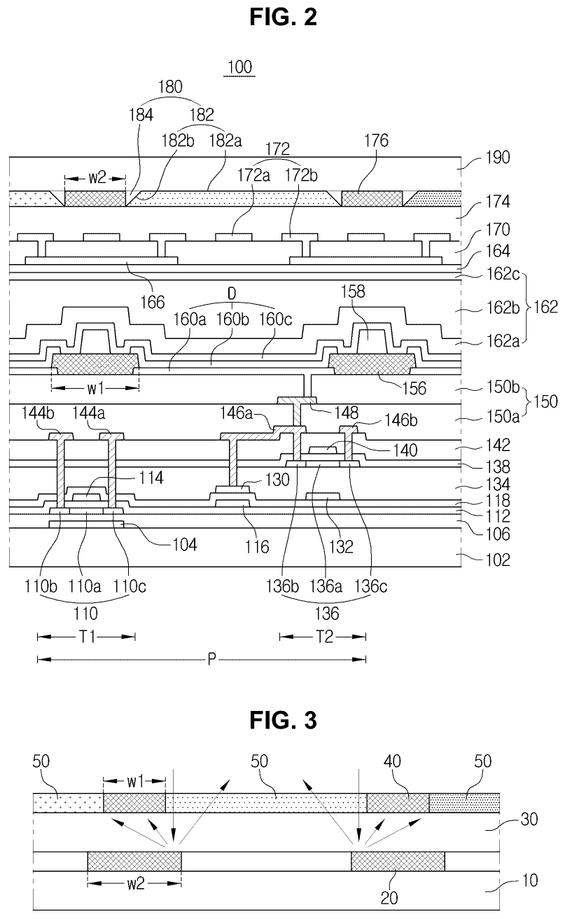

FIG. 2 is a schematic cross-sectional view illustrating an organic light emitting display device according to a first implementation of the present disclosure.

As shown in FIG. 2, an organic light emitting display device 100 includes a substrate 102 including a pixel region P, a light emitting diode D over the substrate 102, a light-shielding bank 156 over the substrate 102, a black matrix 176 over the light-shielding bank 156 and a color filter layer 180 over the light emitting diode D. The light-shielding bank 156 may be referred to as a black bank, a light-shielding pixel definition layer or a black pixel definition layer.

The light emitting diode D is positioned to correspond to the pixel region P, and the light-shielding bank 156 is positioned to correspond to a boundary of the pixel region P. In addition, the black matrix 176 is positioned to correspond to the light-shielding bank 156, and the color filter layer 180 is positioned to correspond to the light emitting diode D.

A plurality of pixel regions are defined on the substrate 102. The substrate 102 may be a glass substrate or a plastic substrate.

In an aspect of the present disclosure, the substrate 102 may have a triple-layered structure including a first polyimide layer, a second polyimide layer and an interlayer inorganic layer between the first and second polyimide layers. The interlayer inorganic layer may be formed of an inorganic insulating material, e.g., silicon oxide or silicon nitride.

A first light-shielding pattern 104 is disposed on the substrate 102. The light through the substrate 102 can be blocked by the first light-shielding pattern 104.

A first buffer layer 106 covering the first light-shielding pattern 104 is disposed on the substrate 102. The first buffer layer 106 may serve to block external moisture and/or oxygen.

A first semiconductor layer 110 corresponding to the first light shielding pattern 104 is disposed on the first buffer layer 106. The first semiconductor layer 110 may include one of a poly-semiconductor material, an amorphous semiconductor material and an oxide semiconductor material. When the first light shielding pattern 104 and the first buffer layer 106 are omitted, the first semiconductor layer 110 may be directly disposed on the substrate 102.

In an aspect of the present disclosure, the first semiconductor layer 110 may be formed of a poly-semiconductor material, e.g., polycrystalline silicon. The first semiconductor layer 110 may include a first channel region 110a, a first source region 110b at one side of the first channel region 110a and a first drain region 110c at the other side of the first channel region 110a. Impurities may be dopped into the first source and drain regions 110b and 110c.

A first gate insulating layer 112 covering the first semiconductor layer 110 is disposed on the first buffer layer 106.

A first gate electrode 114 corresponding to the first channel region 110a of the first semiconductor layer 110 is disposed on the first gate insulating layer 112. In addition, a first capacitor electrode 116, which is spaced apart from the first gate electrode 114, is disposed on the first gate insulating layer 112.

A first interlayer insulating layer 118 covering the first gate electrode 114 and the first capacitor electrode 116 is disposed on the first gate insulating layer 112.

A second capacitor electrode 130 corresponding to the first capacitor electrode 116 and a second light shielding pattern 132 spaced apart from the second capacitor electrode 130 are disposed on the first interlayer insulating layer 118.

A second interlayer insulating layer 134 covering the second capacitor electrode 130 and the second light shielding pattern 132 is disposed on the first interlayer insulating layer 118.

A second semiconductor layer 136 corresponding to the second light shielding pattern 132 is disposed on the second interlayer insulating layer 134. The second semiconductor layer 136 may include one of a poly-semiconductor material, an amorphous semiconductor material and an oxide semiconductor material. In an aspect of the present disclosure, the second semiconductor layer 136 may be formed of an oxide semiconductor material, e.g., indium-gallium-zinc oxide (IGZO), zinc oxide (ZnO), tin oxide (SnO2), copper oxide (Cu2O), nickel oxide (NiO), indium-tin-zinc oxide (ITZO) or indium-aluminum-zinc oxide (IAZO). The second semiconductor layer 136 may include a second channel region 136a, a second source region 136b at one side of the second channel region 136a and a second drain region 136c at the other side of the second channel region 136a. Impurities may be dopped into the second source and drain regions 136b and 136c.

A second gate insulating layer 138 covering the second semiconductor layer 136 is disposed on the second interlayer insulating layer 134.

A second gate electrode 140 corresponding to the second channel region 136a of the second semiconductor layer 136 is disposed on the second gate insulating layer 138.

A third interlayer insulating layer 142 covering the second gate electrode 140 is disposed on the second gate insulating layer 138.

A first source electrode 144a, a first drain electrode 144b, a second source electrode 146a and a second drain electrode 146b are disposed on the third interlayer insulating layer 142.

The first source electrode 144a and the first drain electrode 144b are respectively connected to the first source region 110b and the first drain region 110c via contact holes through the third interlayer insulating layer 142, the second gate insulating layer 138, the second interlayer insulating layer 134, the first interlayer insulating layer 118 and the first gate insulating layer 112. The first source electrode 144a is connected to the first capacitor electrode 116 via a contact hole through the third interlayer insulating layer 142, the second gate insulating layer 138, the second interlayer insulating layer 134 and the first interlayer insulating layer 118.

The second source electrode 146a and the second drain electrode 146b are respectively connected to the second source region 136b and the second drain region 136c via contact holes through the third interlayer insulating layer 142 and the second gate insulating layer 138. The second source electrode 146a is connected to the second capacitor electrode 130 via a contact hole through the third interlayer insulating layer 142, the second gate insulating layer 138 and the second interlayer insulating layer 134.

The first semiconductor layer 110, the first gate electrode 114, the first source electrode 144a and the first drain electrode 144b constitute a first TFT T1, and the second semiconductor layer 136, the second gate electrode 140, the second source electrode 146a and the second drain electrode 146b constitute a second TFT T2.

The organic light emitting display device 100 of the present disclosure includes the first and second TFTs T1 and T2. Each of the first semiconductor layer 110 of the first TFT T1 and the second semiconductor layer 136 of the second TFT T2 may include one of a poly-semiconductor material, an amorphous semiconductor material and an oxide semiconductor material, and at least one of the first semiconductor layer 110 of the first TFT T1 and the second semiconductor layer 136 of the second TFT T2 may include the oxide semiconductor material. In an aspect of the present disclosure, the first semiconductor layer 110 of the first TFT T1 may be formed of the poly-semiconductor material, e.g., polycrystalline silicon, and the second semiconductor layer 136 of the second TFT T2 may be formed of the oxide semiconductor material.

A planarization layer 150 covering the first source and drain electrodes 144a and 144b and the second source and drain electrodes 146a and 146b is disposed on the third interlayer insulating layer 142. The planarization layer 150 may be formed of an organic insulating material, e.g., photo-acryl or BCB.

The planarization layer 150 may include a first planarization layer 150a on the first source and drain electrodes 144a and 144b and the second source and drain electrodes 146a and 146b and a second planarization layer 150b on the first planarization layer 150a.

A connection electrode 148 corresponding to the second source electrode 146a is disposed on the lower planarization layer 150a. The connection electrode 148 may connected to the second source electrode 146a through a contact hole in the lower planarization layer 150a.

The second planarization layer 150b is disposed on the lower planarization layer 150a to cover the connection electrode 148, and a first electrode 160a is disposed on the second planarization layer 150b. The first electrode 160a corresponds to the connection electrode 148 and is connected to the connection electrode 148 through a contact hole in the second planarization layer 150b.

For example, the first electrode 160a is separately formed in each pixel region P. The first electrode 160a may be an anode and may include a transparent conductive oxide (TCO) layer, which is formed of a conductive material, e.g., a transparent conductive oxide material, having a relatively high work function, and a reflective layer.

For example, the transparent conductive oxide material may include at least one of indium-tin-oxide (ITO), indium-zinc-oxide (IZO), indium-tin-zinc oxide (ITZO), tin oxide (SnO), zinc oxide (ZnO), indium-copper-oxide (ICO) and aluminum-zinc-oxide (Al:ZnO, AZO), and the reflective layer may include at least one of silver (Ag), an alloy of Ag and one of palladium (Pd), Cu, In and Nd and aluminum-palladium-copper alloy (APC). For example, the first electrode 160a may have a double-layered structure of Ag/ITO or APC/ITO or a triple-layered structure of ITO/Ag/ITO or ITO/APC/ITO.

The light-shielding bank 156 is formed on the second planarization layer 150b at a boundary of the pixel region. The light-shielding bank 156 covers an edge of the first electrode 160a and has a first opening to expose a center of the first electrode 160a. The light-shielding bank 156 may extend into a portion of the non-display area NDA. The light-shielding bank 156 may include an organic insulating material and a light-absorbing particle, e.g., a black particle, to have a light-absorbing property. For example, the organic insulating material may be at least one of photo-acryl, benzocyclobutene (BCB) and polyimide, and the light-absorbing particle may be at least one of carbon black, carbon nano-tube and graphene.

The light-shielding bank 156 may have an optical density (OD) being 0.2 or more. The light-shielding bank 156 can absorb most of the light and transmit some of the light.

A spacer 158 is disposed on the light-shielding bank 156. The spacer 158 may be omitted.

An organic light emitting layer 160b covering the first electrode 160a, the light-shielding bank 156 and the spacer 158 is disposed. The organic light emitting layer 160b contacts the first electrode 160a in the first opening of the bank 156. Namely, the organic light emitting layer 160b may be formed to contact an upper surface of the first electrode 160a, a side surface and an upper surface of the light-shielding bank 156 and a side surface and an upper surface of the spacer 158.

For example, the organic light emitting layer 160b may include an emitting material layer (EML) including a host and a dopant. In addition, the organic light emitting layer 160b may further include at least one of a hole injection layer (HIL), a hole transporting layer (HTL), an electron blocking layer (EBL), a hole blocking layer (HBL), an electron transporting layer (ETL) and an electron injection layer (EIL) to have a multi-layered structure.

A second electrode 160c is formed over the substrate 102 where the organic emitting layer 160b is formed. The second electrode 160c covers an entire surface of the display area. The second electrode 160c may be formed of at least one of ITO, IZO, Al, Ag, Cu, Pb, magnesium (Mg), Mo, Ti, or an alloy thereof, and have a single-layered structure or a multi-layered structure. The second electrode 160c may have a thin profile (small thickness) to provide a light transmittance property (or a semi-transmittance property).

The first electrode 160a, the organic light emitting layer 160b and the second electrode 160c constitute a light emitting diode D. The light emitting diode D may emit the red, green and blue light in the red, green and blue pixel region, respectively.

In the organic light emitting display device 100, the light from the organic light emitting layer 160b passes through the second electrode 160c to display an image. Namely, the organic light emitting display device 100 of the present disclosure is a top-emission type display device.

An encapsulation layer (or encapsulation film) 162 is formed on the second electrode 160c to prevent penetration of moisture into the light emitting diode D. The encapsulation layer 162 may cover an entire substrate 102. The encapsulation layer 162 includes a first inorganic insulating layer 162a, an organic insulating layer 162b and a second inorganic insulating layer 162c sequentially stacked, but it is not limited thereto.

A second buffer layer 164 is disposed on the encapsulating layer 162. The second buffer layer 164 may serve to block external moisture and/or oxygen.

A bridge pattern 166 is disposed on the second buffer layer 164. The bridge pattern 166 may correspond to a boundary of the pixel region P. For example, the bridge pattern 266 may be formed of one of ITO, IZO, Al, Ag, Cu, Pb, Mg, Mo, Ti, or an alloy thereof, and have a single-layered structure or a multi-layered structure.

When the second buffer layer 164 is omitted, the bridge pattern 166 may be formed directly on the encapsulation layer 162.

A fourth interlayer insulating layer 170 is disposed on the bridge pattern 166 and over an entire substrate 102.

A touch electrode 172 is disposed on the fourth interlayer insulating layer 170. The touch electrode 172 may include a plurality of first touch electrodes 172a and a plurality of second touch electrodes 172b. The first touch electrodes 172a are spaced part from each other, and the second touch electrodes 172b are disposed between the first touch electrodes. The second touch electrodes 172b are connected to each other through the bridge pattern 166 on the fourth interlayer insulating layer 170.

A first protection layer 174 is disposed on the first and second touch electrodes 172a and 172b.

A black matrix 176 is disposed on the first protection layer 174. The black matrix 176 is positioned at a boundary of the pixel region P and has a second opening in correspondence to the light emitting diode D. Namely, the second opening of the black matrix 176 corresponds to the first opening of the light-shielding bank 156.

The second opening of the black matrix 176 has an area being greater than the first opening of the light-shielding bank 156. The light-shielding bank 156 has a first width w1, and the black matrix 176 has a second width w2 being smaller than the first width w1. When an area of the second opening of the black matrix 176 is equal to or smaller than that of the first opening of the light-shielding bank 156, a viewing angle of the organic light emitting display device 100 may be decreased.

The color filter layer 180 corresponding to the second opening of the black matrix 176 is disposed on the first protection layer 174. The color filter layer 180 may include a red color filter corresponding to the red pixel region, a green color filter corresponding to the green pixel region and a blue color filter corresponding to the blue pixel region.

The color filter layer 180 includes a color filter pattern 182 having an upper surface 182a and an inclined side surface 182b and a transparent resin pattern 184 covering the inclined side surface 182b. Namely, the transparent resin pattern 184 fills a space between the inclined side surface 182b of the color filter pattern 182 and the black matrix 176. The color filter pattern 182 and the transparent resin pattern 184 may form a flat top surface.

The color filter pattern 182 has a first refractive index, and the transparent resin pattern 184 has a second refractive index being greater than the first refractive index. For example, the first refractive index may be in a range of 1.3 to 1.5, and the second refractive index may be in a range of 1.5 to 1.8. In an aspect of the present disclosure, the first refractive index may be in a range of 1.34 to 1.5, and the second refractive index may be in a range of 1.5 to 1.7. A difference between the first refractive index and the second refractive index may be in a range of 0.05 to 0.1, preferably 0.07 to 0.1.

The color filter pattern 182 includes a first organic insulating material and a first color particle. The first organic insulating material may be selected from the group that includes polymethylmethacrylate, polycarbonate, polyacrylate, polyurethane, epoxy, polyester and polyimide, but it is not limited thereto. The first color particle may be a pigment or a dye.

The transparent resin pattern 184 includes a second organic insulating material. For example, the second organic insulating material may be selected from the group that includes polydimethylsiloxane, polysiloxane, polytetrafluoroethylene, fluorinated ethylene propylene and fluorinated polyimide, but it is not limited thereto.

A second protection layer 190 is disposed on the black matrix 176 and the color filter layer 180 and over an entire substrate 102.

The display device 100 according to the first implementation of the present disclosure includes the black matrix 176 disposed at a boundary of the pixel region P and the color filter layer 180 corresponding to the pixel region P without a polarization plate so that ambient light reflection and brightness degradation can be minimized.

In addition, since the display device 100 further includes the light-shielding bank 156 surrounding the light emitting diode and disposed at a boundary of the pixel region P, the ambient light reflection can be further decreased, and a leakage current from the first and second TFTs T1 and T2 by the ambient light reflection can be reduced.

Moreover, since the black matrix 176 has a width being smaller than the light-shielding bank 156, a viewing angle decrease by the black matrix 176 can be reduced.

Furthermore, since the color filter layer 180 includes the color filter pattern 182 having the inclined side surface 182b and the first refractive index and the transparent resin pattern 184 corresponding to the inclined side surface 182b and having the second refractive index, which is greater than the first refractive index, the ambient light reflection can be further decreased.

FIG. 3 is a schematic cross-sectional view illustrating an arrangement of a light-shielding bank and a black matrix in organic light emitting display device according to another implementation of the present disclosure.

Referring to FIG. 3, an organic light emitting display device includes a substrate 10, a light-shielding bank 20 disposed on the substrate 10 and having a first width w1, an insulating layer 30 covering the light-shielding bank 20, a black matrix 40 disposed on the insulating layer 30 in correspondence to the light-shielding bank 20 and having a second width w2, which is smaller than the first width w1, and a color filter layer 50 disposed in an opening of the black matrix 40.

In the above organic light emitting display device, an ambient light passing through the color filter layer 50 is incident onto the light-shielding bank 20, which is not covered by the black matrix 40, and a part of the ambient light is reflected by the light-shielding bank 20 toward the color filter layer 50. As a result, a contrast ratio of the organic light emitting display device can be decreased. Namely, although the organic light emitting display device includes the light-shielding bank 20, the black matrix 40 and the color filter layer 50, a display quality can be decreased by the ambient light reflection.

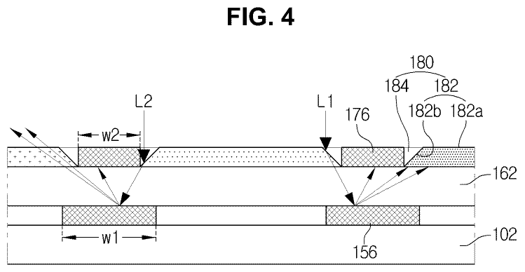

Referring to FIG. 4, which is a schematic cross-sectional view for explaining a decrease of an ambient light reflection in the organic light emitting display device according to the first implementation of the present disclosure, the organic light emitting display device 100 according to the first implementation of the present disclosure includes the light-shielding bank 156 disposed on the substrate 102, the encapsulation layer 162 covering the light-shielding bank 156, the black matrix 176 disposed on the encapsulation layer 162 and corresponding to the light-shielding bank 156 and the color filter layer 180 in an opening of the black matrix 176, and the color filter layer 180 includes the color filter pattern 182 having the upper surface 182a and the inclined side surface 182b and the transparent resin pattern 184 corresponding to the inclined side surface 182b. In addition, the light-shielding bank 156 has a first width w1, and the black matrix 176 has a second width w2 being smaller than the first width w1. Moreover, the transparent resin pattern 184 has a refractive index being greater than the color filter pattern 182.

In the organic light emitting display device 100, an ambient light L1 is refracted when passing through the transparent resin pattern 184 and the color filter layer 182 so that the ambient light L1 is incident onto the light-shielding bank 156 covered with the black matrix 176. The ambient light reflected by the light-shielding bank 156 is absorbed by the light-shielding bank 156 and the black matrix 176 so that the ambient light reflection can be minimized or reduced. Accordingly, the ambient light reflection and the brightness degradation can be reduced or prevented without a polarization plate so that the organic light emitting display device 100 can provide high quality images.

However, an ambient light L2, which is incident to an end portion of the inclined side surface 182b of the color filter pattern 182 cannot be filtered by the color filter pattern 182, the ambient light L2 incident to a first pixel region, e.g., a red pixel region, is reflected by the light-shielding bank 156 and passes through the color filter layer in a second pixel region, e.g., a green pixel region or a blue pixel region. Accordingly, a display quality of the organic light emitting display device 100 can be decreased by the ambient light reflection.

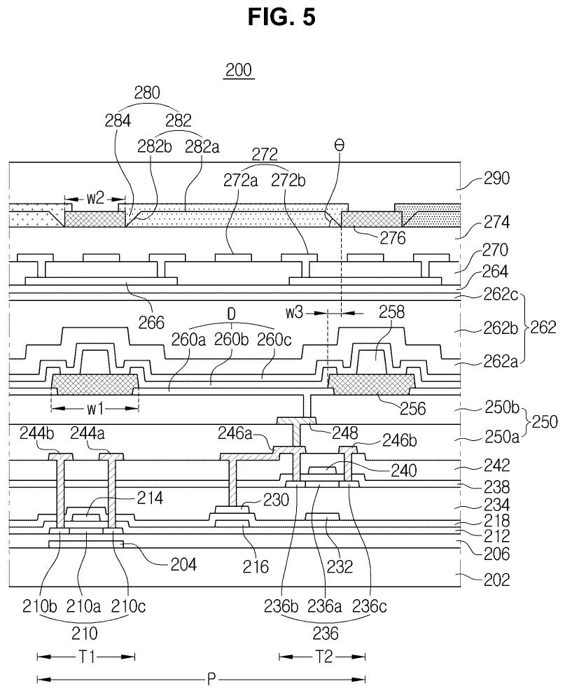

FIG. 5 is a schematic cross-sectional view illustrating an organic light emitting display device according to a second implementation of the present disclosure.

As shown in FIG. 5, an organic light emitting display device 200 includes a substrate 202 including a pixel region P, a light emitting diode D over the substrate 202 and corresponding to the pixel region P, a light-shielding bank 256 over the substrate 202 and positioned at a boundary of the pixel region P, a black matrix 276 over the light-shielding bank 256 and corresponding to the light-shielding bank 256, and a color filter layer 280 disposed on and corresponding to the light emitting diode D.

A plurality of pixel regions are defined on the substrate 202. The substrate 202 may be a glass substrate or a plastic substrate. For example, the substrate 202 may be one of polyimide (PI) substrate, polyethersulfone (PES) substrate, polyethylenenaphthalate (PEN) substrate, polyethylene terephthalate (PET) substrate and polycarbonate (PC) substrate.

In an aspect of the present disclosure, the substrate may have a triple-layered structure including a first polyimide layer, a second polyimide layer and an interlayer inorganic layer between the first and second polyimide layers. The interlayer inorganic layer may be formed of an inorganic insulating material, e.g., silicon oxide or silicon nitride.

A first light-shielding pattern 204 is disposed on the substrate 202. The light through the substrate 202 can be blocked by the first light-shielding pattern 204. For example, the first light-shielding pattern 204 may be formed of a metallic material, e.g., molybdenum (Mo), aluminum (Al), chromium (Cr), gold (Au), titanium (Ti), nickel (Ni), neodymium (Nd), copper (Cu), or an alloy thereof, and have a single-layered structure or a multi-layered structure.

A buffer layer may be disposed between the substrate 202 and the first light-shielding pattern 204.

A first buffer layer 206 covering the first light-shielding pattern 204 is disposed on the substrate 202. The first buffer layer 206 may serve to block external moisture and/or oxygen. For example, the first buffer layer 206 may be formed of an inorganic insulating material, e.g., silicon oxide or silicon nitride, and have a single-layered structure or a multi-layered structure.

A first semiconductor layer 210 corresponding to the first light shielding pattern 204 is disposed on the first buffer layer 206. The first semiconductor layer 210 may include one of a poly-semiconductor material, an amorphous semiconductor material and an oxide semiconductor material. When the first light shielding pattern 204 and the first buffer layer 206 are omitted, the first semiconductor layer 210 may be directly disposed on the substrate 202.

In an aspect of the present disclosure, the first semiconductor layer 210 may be formed of a poly-semiconductor material, e.g., polycrystalline silicon. The first semiconductor layer 210 may include a first channel region 210a, a first source region 210b at one side of the first channel region 210a and a first drain region 210c at the other side of the first channel region 210a. Impurities may be dopped into the first source and drain regions 210b and 210c.

A first gate insulating layer 212 covering the first semiconductor layer 210 is disposed on the first buffer layer 206. The first gate insulating layer 212 may be formed of an inorganic insulating material, e.g., silicon oxide or silicon nitride, and have a single-layered structure or a multi-layered structure.

A first gate electrode 214 corresponding to the first channel region 210a of the first semiconductor layer 210 is disposed on the first gate insulating layer 212. In addition, a first capacitor electrode 216, which is spaced apart from the first gate electrode 214, is disposed on the first gate insulating layer 212.

The first gate electrode 214 and the first capacitor electrode 216 may be disposed on the same layer and be formed of the same material. For example, each of the first gate electrode 214 and the first capacitor electrode 216 may be formed of a metallic material, e.g., Mo, Al, Cr, Au, Ti, Ni, Nd, Cu, or an alloy thereof, and have a single-layered structure or a multi-layered structure.

A first interlayer insulating layer 218 covering the first gate electrode 214 and the first capacitor electrode 216 is disposed on the first gate insulating layer 212. The first interlayer insulating layer 218 may be formed of an inorganic insulating material, e.g., silicon oxide or silicon nitride, and have a single-layered structure or a multi-layered structure.

A second capacitor electrode 230 corresponding to the first capacitor electrode 216 and a second light shielding pattern 232 spaced apart from the second capacitor electrode 230 are disposed on the first interlayer insulating layer 218.

The second capacitor electrode 230 and the second light shielding pattern 232 may be disposed on the same layer and be formed of the same material. For example, each of the second capacitor electrode 230 and the second light shielding pattern 232 may be formed of a metallic material, e.g., Mo, Al, Cr, Au, Ti, Ni, Nd, Cu, or an alloy thereof, and have a single-layered structure or a multi-layered structure.

A second interlayer insulating layer 234 covering the second capacitor electrode 230 and the second light shielding pattern 232 is disposed on the first interlayer insulating layer 218. The external moisture and/or oxygen can be blocked by the second interlayer insulating layer 234. For example, the second interlayer insulating layer 234 may be formed of an inorganic insulating material, e.g., silicon oxide or silicon nitride, or an organic insulating material, e.g., photo-acryl or benzocyclobutene (BCB), and have a single-layered structure or a multi-layered structure.

A second semiconductor layer 236 corresponding to the second light shielding pattern 232 is disposed on the second interlayer insulating layer 234. The second semiconductor layer 236 may include one of a poly-semiconductor material, an amorphous semiconductor material and an oxide semiconductor material.

In an aspect of the present disclosure, the second semiconductor layer 236 may be formed of an oxide semiconductor material, e.g., indium-gallium-zinc oxide (IGZO), zinc oxide (ZnO), tin oxide (SnO2), copper oxide (Cu2O), nickel oxide (NiO), indium-tin-zinc oxide (ITZO) or indium-aluminum-zinc oxide (IAZO).

The second semiconductor layer 236 may include a second channel region 236a, a second source region 236b at one side of the second channel region 236a and a second drain region 236c at the other side of the second channel region 236a. Impurities may be dopped into the second source and drain regions 236b and 236c.

A second gate insulating layer 238 covering the second semiconductor layer 236 is disposed on the second interlayer insulating layer 234. The second gate insulating layer 238 may be formed of an inorganic insulating material, e.g., silicon oxide or silicon nitride, and have a single-layered structure or a multi-layered structure.

A second gate electrode 240 corresponding to the second channel region 236a of the second semiconductor layer 236 is disposed on the second gate insulating layer 236. For example, the second gate electrode 240 may be formed of a metallic material, e.g., Mo, Al, Cr, Au, Ti, Ni, Nd, Cu, or an alloy thereof, and have a single-layered structure or a multi-layered structure.

A third interlayer insulating layer 242 covering the second gate electrode 240 is disposed on the second gate insulating layer 238. The third interlayer insulating layer 242 may be formed of an inorganic insulating material, e.g., silicon oxide or silicon nitride, and have a single-layered structure or a multi-layered structure.

A first source electrode 244a, a first drain electrode 244b, a second source electrode 246a and a second drain electrode 246b are disposed on the third interlayer insulating layer 242.

The first source electrode 244a and the first drain electrode 244b are respectively connected to the first source region 210b and the first drain region 210c via contact holes through the third interlayer insulating layer 242, the second gate insulating layer 238, the second interlayer insulating layer 234, the first interlayer insulating layer 218 and the first gate insulating layer 212. The first source electrode 244a is connected to the first capacitor electrode 216 via a contact hole through the third interlayer insulating layer 242, the second gate insulating layer 238, the second interlayer insulating layer 234 and the first interlayer insulating layer 218.

The second source electrode 246a and the second drain electrode 246b are respectively connected to the second source region 236b and the second drain region 236c via contact holes through the third interlayer insulating layer 242 and the second gate insulating layer 238. The second source electrode 246a is connected to the second capacitor electrode 230 via a contact hole through the third interlayer insulating layer 242, the second gate insulating layer 238 and the second interlayer insulating layer 234.

The first source and drain electrodes 244a and 244b and the second source and drain electrodes 246a and 246b may be disposed on the same layer and formed of the same material. For example, each of the first source and drain electrodes 244a and 244b and the second source and drain electrodes 246a and 246b may be formed of a metallic material, e.g., Mo, Al, Cr, Au, Ti, Ni, Nd, Cu, or an alloy thereof, and have a single-layered structure or a multi-layered structure.

The first semiconductor layer 210, the first gate electrode 214, the first source electrode 244a and the first drain electrode 244b constitute a first TFT T1, and the second semiconductor layer 236, the second gate electrode 240, the second source electrode 246a and the second drain electrode 246b constitute a second TFT T2. For example, the first TFT T1 may be a switching TFT, and the second TFT may be a driving TFT. In addition, the first and second capacitor electrodes 216 and 230 constitute a storage capacitor.

The organic light emitting display device 200 of the present disclosure includes the first and second TFTs T1 and T2. Each of the first semiconductor layer 210 of the first TFT T1 and the second semiconductor layer 236 of the second TFT T2 may include one of a poly-semiconductor material, an amorphous semiconductor material and an oxide semiconductor material, and at least one of the first semiconductor layer 210 of the first TFT T1 and the second semiconductor layer 236 of the second TFT T2 may include the oxide semiconductor material. In an aspect of the present disclosure, the first semiconductor layer 210 of the first TFT T1 may be formed of the poly-semiconductor material, e.g., polycrystalline silicon, and the second semiconductor layer 236 of the second TFT T2 may be formed of the oxide semiconductor material.

In FIG. 5, the first gate electrode 214, the first source electrode 244a and first drain electrode 244b are disposed on the first semiconductor layer 210, and the second gate electrode 240, the second source electrode 246a and the second drain electrode 246b are disposed on the second semiconductor layer 236. Namely, each of the first and second TFTs T1 and T2 has a coplanar structure. Alternatively, in each of the first and second TFTs T1 and T2, a gate electrode may be disposed under a semiconductor layer, and a source and a drain electrode may be disposed on the semiconductor layer. Namely, each of the TFTs T1 and T2 may have an inverted-staggered structure.

A planarization layer 250 covering the first source and drain electrodes 244a and 244b and the second source and drain electrodes 246a and 246b is disposed on the third interlayer insulating layer 242. The planarization layer 250 may be formed of an organic insulating material, e.g., photo-acryl or BCB.

The planarization layer 250 may include a first planarization layer 250a on the first source and drain electrodes 244a and 244b and the second source and drain electrodes 246a and 246b and a second planarization layer 250b on the first planarization layer 250a.

A connection electrode 248 corresponding to the second source electrode 246a is disposed on the first planarization layer 250a. The connection electrode 248 may connected to the second source electrode 246a through a contact hole in the first planarization layer 250a. For example, the connection electrode 248 may be formed of a metallic material, e.g., Mo, Al, Cr, Au, Ti, Ni, Nd, Cu, or an alloy thereof, and have a single-layered structure or a multi-layered structure.

The second planarization layer 250b is disposed on the first planarization layer 250a to cover the connection electrode 248, and a first electrode 260a is disposed on the second planarization layer 250b. The first electrode 260a corresponds to the connection electrode 248 and is connected to the connection electrode 248 through a contact hole in the second planarization layer 250b.

For example, the first electrode 260a is separately formed in each pixel region P. The first electrode 260a may be an anode and may include a transparent conductive oxide (TCO) layer, which is formed of a conductive material, e.g., a transparent conductive oxide material, having a relatively high work function, and a reflective layer.

For example, the transparent conductive oxide material may include at least one of indium-tin-oxide (ITO), indium-zinc-oxide (IZO), indium-tin-zinc oxide (ITZO), tin oxide (SnO), zinc oxide (ZnO), indium-copper-oxide (ICO) and aluminum-zinc-oxide (Al:ZnO, AZO), and the reflective layer may include at least one of silver (Ag), an alloy of Ag and one of palladium (Pd), Cu, In and Nd and aluminum-palladium-copper alloy (APC). For example, the first electrode 260a may have a double-layered structure of Ag/ITO or APC/ITO or a triple-Layered structure of ITO/Ag/ITO or ITO/APC/ITO.

A light-shielding bank 256 is formed on the second planarization layer 250b at a boundary of the pixel region P. The light-shielding bank 256 covers an edge of the first electrode 260a and has a first opening to expose a center of the first electrode 260a. The light-shielding bank 256 may extend into a portion of the non-display area NDA. The light-shielding bank 256 may include an organic insulating material and a light-absorbing particle, e.g., a black particle, to have a light-absorbing property. For example, the organic insulating material may be at least one of photo-acryl, benzocyclobutene (BCB) and polyimide, and the light-absorbing particle may be at least one of carbon black, carbon nano-tube and graphene.

The light-shielding bank 256 may have an optical density (OD) being 1.2 or more. The light-shielding bank 256 can absorb most of the light and transmit some of the light.

A spacer 258 is disposed on the light-shielding bank 256. For example, the spacer 258 may be formed of an organic insulating material, e.g., photo-acryl or BCB, and have a single-layered structure or a multi-layered structure. The spacer 258 may be omitted.

An organic light emitting layer 260b covering the first electrode 260a, the light-shielding bank 256 and the spacer 258 is disposed. The organic light emitting layer 260b contacts the first electrode 260a in the first opening of the light-shielding bank 256. Namely, the organic light emitting layer 260b may be formed to contact an upper surface of the first electrode 260a, a side surface and an upper surface of the light-shielding bank 256 and a side surface and an upper surface of the spacer 258.

For example, the organic light emitting layer 260b may include an emitting material layer (EML) including a host and a dopant. In addition, the organic light emitting layer 260b may further include at least one of a hole injection layer (HIL), a hole transporting layer (HTL), an electron blocking layer (EBL), a hole blocking layer (HBL), an electron transporting layer (ETL) and an electron injection layer (EIL) to have a multi-layered structure.

A second electrode 260c is formed over the substrate 202 where the organic emitting layer 260b is formed. The second electrode 260c covers an entire surface of the display area. The second electrode 260c may be formed of at least one of ITO, IZO, Al, Ag, Cu, Pb, magnesium (Mg), Mo, Ti, or an alloy thereof, and have a single-layered structure or a multi-layered structure. The second electrode 260c may have a thin profile (small thickness) to provide a light transmittance property (or a semi-transmittance property).

The first electrode 260a, the organic light emitting layer 260b and the second electrode 260c constitute a light emitting diode D. The light emitting diode D may emit the red, green and blue light in the red, green and blue pixel region, respectively.

In the organic light emitting display device 200, the light from the organic light emitting layer 260b passes through the second electrode 260c to display an image. Namely, the organic light emitting display device 200 of the present disclosure is a top-emission type display device.

An encapsulation layer (or encapsulation film) 262 is formed on the second electrode 260c to prevent penetration of moisture into the light emitting diode D. The encapsulation layer 262 may cover an entire substrate 202. The encapsulation layer 262 includes a first inorganic insulating layer 262a, an organic insulating layer 262b and a second inorganic insulating layer 262c sequentially stacked, but it is not limited thereto.

Each of the first and second inorganic insulating layers 262a and 262c may be formed of an inorganic insulating material, e.g., silicon oxide or silicon nitride. The organic insulating layer 262b may be formed of an organic insulating material, e.g., acryl resin, epoxy resin, phenolic resin, polyamide resin or polyimide resin.

A second buffer layer 264 is disposed on the encapsulating layer 262. The second buffer layer 264 may serve to block external moisture and/or oxygen. The second buffer layer 264 may be formed of an inorganic insulating material, e.g., silicon oxide or silicon nitride, and have a single-layered structure or a multi-layered structure.

A bridge pattern 266 is disposed on the second buffer layer 264. The bridge pattern 266 may correspond to a boundary of the pixel region P. For example, the bridge pattern 266 may be formed of one of ITO, IZO, Al, Ag, Cu, Pb, Mg, Mo, Ti, or an alloy thereof, and have a single-layered structure or a multi-layered structure.

When the second buffer layer 264 is omitted, the bridge pattern 266 may be formed directly on the encapsulation layer 262.

A fourth interlayer insulating layer 270 is disposed on the bridge pattern 266 and over an entire substrate 202. The fourth interlayer insulating layer 270 may be formed of an inorganic insulating material, e.g., silicon oxide or silicon nitride, or an organic insulating material, e.g., photo-acryl or BCB, and have a single-layered structure or a multi-layered structure.

A touch electrode 272 is disposed on the fourth interlayer insulating layer 270. The touch electrode 272 may include a plurality of first touch electrodes 272a and a plurality of second touch electrodes 272b. The first touch electrodes 272a are spaced part from each other, and the second touch electrodes 272b are disposed between the first touch electrodes. The second touch electrodes 272b are connected to each other through the bridge pattern 266 on the fourth interlayer insulating layer 270.

For example, each of the first and second touch electrodes 272a and 272b may be formed of one of ITO, IZO, Al, Ag, Cu, Pb, Mg, Mo, Ti, or an alloy thereof, and have a single-layered structure or a multi-layered structure.

A first protection layer 274 is disposed on the first and second touch electrodes 272a and 272b. The first protection layer 274 may be formed of an inorganic insulating material, e.g., silicon oxide or silicon nitride, or an organic insulating material, e.g., photo-acryl or BCB, and have a single-layered structure or a multi-layered structure.

A black matrix 276 is disposed on the first protection layer 274. The black matrix 276 is positioned at a boundary of the pixel region P and has a second opening in correspondence to the light emitting diode D. Namely, the second opening of the black matrix 276 corresponds to the first opening of the light-shielding bank 256.

The second opening of the black matrix 276 has an area being greater than the first opening of the light-shielding bank 256. The light-shielding bank 256 has a first width w1, and the black matrix 276 has a second width w2 being smaller than the first width w1. When an area of the second opening of the black matrix 276 is equal to or smaller than that of the first opening of the light-shielding bank 256, a viewing angle of the organic light emitting display device 200 may be decreased.

For example, the black matrix 276 may completely overlap the light-shielding bank 256, and an end of the light-shielding bank 256 protrudes from an end of the black matrix 276 by a third width w3. In other words, an end of the light-shielding bank 256 with the third width w3 is not covered by the black matrix 276.

The color filter layer 280 corresponding to the second opening of the black matrix 276 is disposed on the first protection layer 274. The color filter layer 280 may include a red color filter corresponding to the red pixel region, a green color filter corresponding to the green pixel region and a blue color filter corresponding to the blue pixel region.

The color filter layer 280 includes a first color filter pattern 282 having an upper surface 282a and an inclined side surface 282b and a second color filter pattern 284 covering the first color filter pattern 282.

The second color filter pattern 284 covers the upper surface 282a and the inclined side surface 282b of the first color filter pattern 282. Namely, the second color filter pattern 284 fills a space between the black matrix 276 and the inclined side surface 282b of the first color filter pattern 282 and covers the upper surface 282a of the first color filter pattern 282. The second color filter pattern 284 provides a flat top surface.

The first color filter pattern 282 has a first thickness, and the second color filter pattern 282b has a second thickness being equal to or smaller than the first thickness. In an aspect of the present disclosure, a thickness of the second color filter pattern 284 may be smaller than that of the first color filter pattern 282.

The first color filter pattern 282 has a first refractive index, and the second color filter pattern 284 has a second refractive index being greater than the first refractive index. For example, the first refractive index may be in a range of 1.3 to 1.5, and the second refractive index may be in a range of 1.5 to 1.8. In an aspect of the present disclosure, the first refractive index may be in a range of 1.34 to 1.5, and the second refractive index may be in a range of 1.5 to 1.7. A difference between the first refractive index and the second refractive index may be in a range of 0.05 to 0.1, preferably 0.07 to 0.1.

The first color filter pattern 282 includes a first organic insulating material and a first color particle. The first organic insulating material may be selected from the group that includes polymethylmethacrylate, polycarbonate, polyacrylate, polyurethane, epoxy, polyester and polyimide, but it is not limited thereto. The first color particle may be a pigment or a dye.

The second color filter pattern 284 includes a second organic insulating material and a second color particle. The second organic insulating material may be selected from the group that includes polydimethylsiloxane, polysiloxane, polytetrafluoroethylene, fluorinated ethylene propylene and fluorinated polyimide, but it is not limited thereto.

The second color particle may be a pigment or a dye. The first color particle and the second color particle transmit the light having the same wavelength range and absorb the light having the rest wavelength range. Namely, an absorption wavelength range of the first color particle may be same as an absorption wavelength range of the second color particle. For example, each of the first and second color particles may be a red color particle.

The inclined side surface 282b of the first color filter pattern 282 has a first angle θ with respect to the first protective layer 274 or the substrate 202.

The first angle θ between the inclined side surface 282b of the first color filter pattern 282 and at least one of the first protective layer 274 or the substrate 202 may satisfy an Equation (1).

wd≤(T(CF1)/tanθ)≤(w1)/2 Equation (1)

In Equation (1), wd is a difference between a width of the light-shielding bank and a width of the black matrix, T(CF1) is a thickness of the first color filter pattern, θ is angle between the inclined side surface of the first color filter pattern and at least one of the first protective layer (or the substrate), and w1 is a width of the light-shielding bank.

A second protection layer 290 is disposed on the black matrix 276 and the color filter layer 280 and over an entire substrate 202. The second protection layer 290 may be formed of an inorganic insulating material, e.g., silicon oxide or silicon nitride, or an organic insulating material, e.g., photo-acryl or benzocyclobutene (BCB), and have a single-layered structure or a multi-layered structure.

The display device 200 according to the second implementation of the present disclosure includes the black matrix 276 disposed at a boundary of the pixel region P and the color filter layer 280 corresponding to the pixel region P without a polarization plate so that ambient light reflection and brightness degradation can be minimized.

In addition, since the display device 200 further includes the light-shielding bank 256 surrounding the light emitting diode and disposed at a boundary of the pixel region P, the ambient light reflection can be further decreased, and a leakage current from the first and second TFTs T1 and T2 by the ambient light reflection can be reduced.

Moreover, since the black matrix 276 has a width being smaller than the light-shielding bank 256, a viewing angle decrease by the black matrix 276 can be reduced.

Further, since the color filter layer 280 includes the first color filter pattern 282 having the inclined side surface 282b and the first refractive index and the second color filter pattern 284 covering the first color filter pattern 282 and having the second refractive index, which is greater than the first refractive index, the ambient light reflection can be further decreased.

Furthermore, since the ambient light through an edge of the first color filter pattern 282 passes through the second color filter pattern 284, an ambient light reflection in adjacent pixel region, which may be occurred in the display device according to the first implementation of the present disclosure, can be reduced.

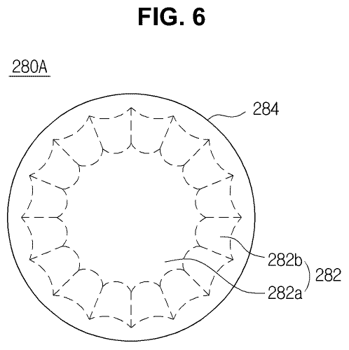

FIG. 6 is a schematic plane view illustrating a color filter layer in organic light emitting display device according to another implementation of the present disclosure.

As shown in FIG. 6, a color filter layer 280A includes a first color filter pattern 282 and a second color filter pattern 284 over the first color filter pattern 282, and the first color filter pattern 282 includes an upper surface 282a and an inclined side surface 282b having a curved shape.

The upper surface 282a of the first color filter pattern 282 has a planar sawtooth shape (or a planar serrated shape), and the inclined side surface 282b of the first color filter pattern 282 has a concave curved shape.

Referring to FIG. 5 with FIG. 6, the color filter layer 280A is disposed in an area surrounded by the black matrix 276, and the inclined side surface 282b having a concave curved shape faces the black matrix 276. Namely, the color filter layer 280A is disposed in the opening of the black matrix 276.

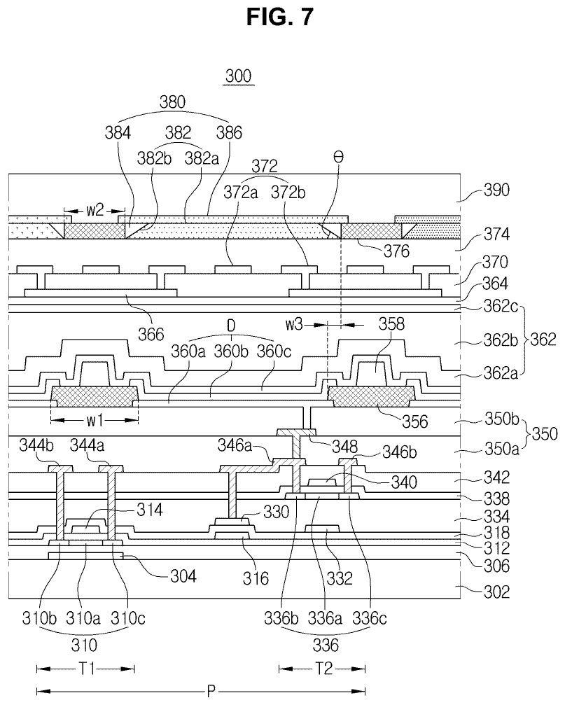

FIG. 7 is a schematic cross-sectional view illustrating an organic light emitting display device according to a third implementation of the present disclosure.

As shown in FIG. 7, an organic light emitting display device 300 includes a substrate 302 including a pixel region P, a light emitting diode D over the substrate 302 and corresponding to the pixel region P, a light-shielding bank 356 over the substrate 302 and positioned at a boundary of the pixel region P, a black matrix 376 over the light-shielding bank 356 and corresponding to the light-shielding bank 356, and a color filter layer 380 disposed on and corresponding to the light emitting diode D.

A plurality of pixel regions are defined on the substrate 302. The substrate 302 may be a glass substrate or a plastic substrate. In an aspect of the present disclosure, the substrate 302 may have a triple-layered structure including a first polyimide layer, a second polyimide layer and an interlayer inorganic layer between the first and second polyimide layers.

A first light-shielding pattern 304 is disposed on the substrate 302, and a first buffer layer 306 covering the first light-shielding pattern 304 is disposed on the substrate 302.

A first semiconductor layer 310 corresponding to the first light shielding pattern 304 is disposed on the first buffer layer 306. The first semiconductor layer 310 may include one of a poly-semiconductor material, an amorphous semiconductor material and an oxide semiconductor material. When the first light shielding pattern 304 and the first buffer layer 306 are omitted, the first semiconductor layer 310 may be directly disposed on the substrate 302.

In an aspect of the present disclosure, the first semiconductor layer 310 may be formed of a poly-semiconductor material, e.g., polycrystalline silicon. The first semiconductor layer 310 may include a first channel region 310a, a first source region 310b at one side of the first channel region 310a and a first drain region 310c at the other side of the first channel region 310a. Impurities may be dopped into the first source and drain regions 310b and 310c.

A first gate insulating layer 312 covering the first semiconductor layer 310 is disposed on the first buffer layer 306.

A first gate electrode 314 corresponding to the first channel region 310a of the first semiconductor layer 310 is disposed on the first gate insulating layer 312. In addition, a first capacitor electrode 316, which is spaced apart from the first gate electrode 314, is disposed on the first gate insulating layer 312.

A first interlayer insulating layer 318 covering the first gate electrode 314 and the first capacitor electrode 316 is disposed on the first gate insulating layer 312.

A second capacitor electrode 330 corresponding to the first capacitor electrode 316 and a second light shielding pattern 332 spaced apart from the second capacitor electrode 330 are disposed on the first interlayer insulating layer 318.

A second interlayer insulating layer 334 covering the second capacitor electrode 330 and the second light shielding pattern 332 is disposed on the first interlayer insulating layer 318.

A second semiconductor layer 336 corresponding to the second light shielding pattern 332 is disposed on the second interlayer insulating layer 334. The second semiconductor layer 336 may include one of a poly-semiconductor material, an amorphous semiconductor material and an oxide semiconductor material.

In an aspect of the present disclosure, the second semiconductor layer 336 may be formed of an oxide semiconductor material, e.g., indium-gallium-zinc oxide (IGZO), zinc oxide (ZnO), tin oxide (SnO2), copper oxide (Cu2O), nickel oxide (NiO), indium-tin-zinc oxide (ITZO) or indium-aluminum-zinc oxide (IAZO).

The second semiconductor layer 336 may include a second channel region 336a, a second source region 336b at one side of the second channel region 336a and a second drain region 336c at the other side of the second channel region 336a. Impurities may be dopped into the second source and drain regions 336b and 336c.

A second gate insulating layer 338 covering the second semiconductor layer 336 is disposed on the second interlayer insulating layer 334.

A second gate electrode 340 corresponding to the second channel region 336a of the second semiconductor layer 336 is disposed on the second gate insulating layer 336.

A third interlayer insulating layer 342 covering the second gate electrode 340 is disposed on the second gate insulating layer 338.

A first source electrode 344a, a first drain electrode 344b, a second source electrode 346a and a second drain electrode 346b are disposed on the third interlayer insulating layer 342.

The first source electrode 344a and the first drain electrode 344b are respectively connected to the first source region 310b and the first drain region 310c via contact holes through the third interlayer insulating layer 342, the second gate insulating layer 338, the second interlayer insulating layer 334, the first interlayer insulating layer 318 and the first gate insulating layer 312. The first source electrode 344a is connected to the first capacitor electrode 316 via a contact hole through the third interlayer insulating layer 342, the second gate insulating layer 338, the second interlayer insulating layer 334 and the first interlayer insulating layer 318.

The second source electrode 346a and the second drain electrode 346b are respectively connected to the second source region 336b and the second drain region 336c via contact holes through the third interlayer insulating layer 342 and the second gate insulating layer 338. The second source electrode 346a is connected to the second capacitor electrode 330 via a contact hole through the third interlayer insulating layer 342, the second gate insulating layer 338 and the second interlayer insulating layer 334.

The first semiconductor layer 310, the first gate electrode 314, the first source electrode 344a and the first drain electrode 344b constitute a first TFT T1, and the second semiconductor layer 336, the second gate electrode 340, the second source electrode 346a and the second drain electrode 346b constitute a second TFT T2.

A planarization layer 350 covering the first source and drain electrodes 344a and 344b and the second source and drain electrodes 346a and 346b is disposed on the third interlayer insulating layer 342. The planarization layer 350 may be formed of an organic insulating material, e.g., photo-acryl or BCB.

The planarization layer 350 may include a first planarization layer 350a on the first source and drain electrodes 344a and 344b and the second source and drain electrodes 346a and 346b and a second planarization layer 350b on the first planarization layer 350a.

A connection electrode 348 corresponding to the second source electrode 346a is disposed on the first planarization layer 350a. The connection electrode 348 may connected to the second source electrode 346a through a contact hole in the first planarization layer 350a.

The second planarization layer 350b is disposed on the first planarization layer 350a to cover the connection electrode 348, and a first electrode 360a is disposed on the second planarization layer 350b. The first electrode 360a corresponds to the connection electrode 348 and is connected to the connection electrode 348 through a contact hole in the second planarization layer 350b.

For example, the first electrode 360a is separately formed in each pixel region P. The first electrode 360a may be an anode and may include a transparent conductive oxide (TCO) layer, which is formed of a conductive material, e.g., a transparent conductive oxide material, having a relatively high work function, and a reflective layer.

For example, the transparent conductive oxide material may include at least one of indium-tin-oxide (ITO), indium-zinc-oxide (IZO), indium-tin-zinc oxide (ITZO), tin oxide (SnO), zinc oxide (ZnO), indium-copper-oxide (ICO) and aluminum-zinc-oxide (Al:ZnO, AZO), and the reflective layer may include at least one of silver (Ag), an alloy of Ag and one of palladium (Pd), Cu, In and Nd and aluminum-palladium-copper alloy (APC). For example, the first electrode 360a may have a double-layered structure of Ag/ITO or APC/ITO or a triple-Layered structure of ITO/Ag/ITO or ITO/APC/ITO.

A light-shielding bank 356 is formed on the second planarization layer 350b at a boundary of the pixel region P. The light-shielding bank 356 covers an edge of the first electrode 360a and has a first opening to expose a center of the first electrode 360a. The light-shielding bank 356 may extend into a portion of the non-display area NDA. The light-shielding bank 356 may include an organic insulating material and a light-absorbing particle, e.g., a black particle, to have a light-absorbing property. For example, the organic insulating material may be at least one of photo-acryl, benzocyclobutene (BCB) and polyimide, and the light-absorbing particle may be at least one of carbon black, carbon nano-tube and graphene.

The light-shielding bank 356 may have an optical density (OD) being 1.2 or more. The light-shielding bank 356 can absorb most of the light and transmit some of the light.

A spacer 358 is disposed on the light-shielding bank 356. For example, the spacer 358 may be formed of an organic insulating material, e.g., photo-acryl or BCB, and have a single-layered structure or a multi-layered structure. The spacer 358 may be omitted.

An organic light emitting layer 360b covering the first electrode 360a, the light-shielding bank 356 and the spacer 358 is disposed. The organic light emitting layer 360b contacts the first electrode 360a in the first opening of the light-shielding bank 356. Namely, the organic light emitting layer 360b may be formed to contact an upper surface of the first electrode 360a, a side surface and an upper surface of the light-shielding bank 356 and a side surface and an upper surface of the spacer 358.

For example, the organic light emitting layer 360b may include an EML including a host and a dopant. In addition, the organic light emitting layer 360b may further include at least one of an HIL, an HTL, an EBL, an HBL, an ETL and an EIL to have a multi-layered structure.

A second electrode 360c is formed over the substrate 302 where the organic emitting layer 360b is formed. The second electrode 360c covers an entire surface of the display area. The second electrode 360c may be formed of at least one of ITO, IZO, Al, Ag, Cu, Pb, magnesium (Mg), Mo, Ti, or an alloy thereof, and have a single-layered structure or a multi-layered structure. The second electrode 360c may have a thin profile (small thickness) to provide a light transmittance property (or a semi-transmittance property).

The first electrode 360a, the organic light emitting layer 360b and the second electrode 360c constitute a light emitting diode D. The light emitting diode D may emit the red, green and blue light in the red, green and blue pixel region, respectively.

In the organic light emitting display device 300, the light from the organic light emitting layer 360b passes through the second electrode 360c to display an image. Namely, the organic light emitting display device 300 of the present disclosure is a top-emission type display device.

An encapsulation layer (or encapsulation film) 362 is formed on the second electrode 360c to prevent penetration of moisture into the light emitting diode D. The encapsulation layer 362 may cover an entire substrate 302. The encapsulation layer 362 includes a first inorganic insulating layer 362a, an organic insulating layer 362b and a second inorganic insulating layer 362c sequentially stacked, but it is not limited thereto.

A second buffer layer 364 is disposed on the encapsulating layer 362. The second buffer layer 364 may serve to block external moisture and/or oxygen.

A bridge pattern 366 is disposed on the second buffer layer 364, and a fourth interlayer insulating layer 370 is disposed on the bridge pattern 366 and over an entire substrate 302.

A touch electrode 372 is disposed on the fourth interlayer insulating layer 370. The touch electrode 372 may include a plurality of first touch electrodes 372a and a plurality of second touch electrodes 372b. The first touch electrodes 372a are spaced part from each other, and the second touch electrodes 372b are disposed between the first touch electrodes. The second touch electrodes 372b are connected to each other through the bridge pattern 366 on the fourth interlayer insulating layer 370.

A first protection layer 374 is disposed on the first and second touch electrodes 372a and 372b.

A black matrix 376 is disposed on the first protection layer 374. The black matrix 376 is positioned at a boundary of the pixel region P and has a second opening in correspondence to the light emitting diode D. Namely, the second opening of the black matrix 376 corresponds to the first opening of the light-shielding bank 356.

The second opening of the black matrix 376 has an area being greater than the first opening of the light-shielding bank 356. The light-shielding bank 356 has a first width w1, and the black matrix 376 has a second width w2 being smaller than the first width w1. When an area of the second opening of the black matrix 376 is equal to or smaller than that of the first opening of the light-shielding bank 356, a viewing angle of the organic light emitting display device 300 may be decreased.

For example, the black matrix 376 may completely overlap the light-shielding bank 356, and an end of the light-shielding bank 356 protrudes from an end of the black matrix 376 by a third width w3. In other words, an end of the light-shielding bank 356 with the third width w3 is not covered by the black matrix 376.

The color filter layer 380 corresponding to the second opening of the black matrix 376 is disposed on the first protection layer 374. The color filter layer 380 may include a red color filter corresponding to the red pixel region, a green color filter corresponding to the green pixel region and a blue color filter corresponding to the blue pixel region.

The color filter layer 380 includes a first color filter pattern 382 having an upper surface 382a and an inclined side surface 382b, a transparent resin pattern 384 corresponding to the inclined side surface 382b and a second color filter pattern 386 covering the transparent resin pattern 384 and the upper surface 382a of the first color filter pattern 382.

The transparent resin pattern 384 fills a space between the black matrix 376 and the inclined side surface 382b of the first color filter pattern 382. The second color filter pattern 386 covers the first color filter pattern 382 and the transparent resin pattern 384 so that the color filter layer 380 provides a flat top surface.

Namely, the first and second color filter patterns 382 and 386 are spaced apart from each other at an edge of the pixel region P with the transparent resin pattern 384 therebetween, and contact each other at a center of the pixel region P. In another implementation of the present disclosure, the transparent resin pattern 384 may cover both the upper surface 382a and the inclined side surface 382b, and the first and second color filter patterns 382 and 386 may be spaced apart from each other at both an edge and a center of the pixel region P with the transparent resin pattern 384 therebetween.

The first color filter pattern 382 has a first thickness, and the second color filter pattern 386 has a second thickness being equal to or smaller than the first thickness. In an aspect of the present disclosure, a thickness of the second color filter pattern 386 may be smaller than that of the first color filter pattern 382.

The first color filter pattern 382 has a first refractive index, the second color filter pattern 386 has a second refractive index being greater than the first refractive index, and the transparent resin pattern 384 has a third refractive index being equal to or smaller than the second refractive index.

For example, the first refractive index may be in a range of 1.3 to 1.5, and each of the second refractive index and the third refractive index may be in a range of 1.5 to 1.8. In an aspect of the present disclosure, the first refractive index may be in a range of 1.34 to 1.5, and each of the second refractive index and the third refractive index may be in a range of 1.5 to 1.7. A difference between the first refractive index and the second refractive index may be in a range of 0.05 to 0.1, preferably 0.07 to 0.1. A difference between the first refractive index and the third refractive index may be greater than a difference between the second refractive index and the third refractive index.

The first color filter pattern 382 includes a first organic insulating material and a first color particle. The first organic insulating material may be selected from the group that includes polymethylmethacrylate, polycarbonate, polyacrylate, polyurethane, epoxy, polyester and polyimide, but it is not limited thereto. The first color particle may be a pigment or a dye.

The second color filter pattern 386 includes a second organic insulating material and a second color particle, and the transparent resin pattern 384 includes a third organic insulating material. For example, each of the second and third organic insulating materials may be independently selected from the group that includes polydimethylsiloxane, polysiloxane, polytetrafluoroethylene, fluorinated ethylene propylene and fluorinated polyimide, but it is not limited thereto. In an aspect of the present disclosure, the transparent resin pattern 384 may be formed of the same material as the second color filter pattern 386 without the second color particle.

The second color particle may be a pigment or a dye. The first color particle and the second color particle transmit the light having the same wavelength range and absorb the light having the rest wavelength range. For example, each of the first and second color particles may be a red color particle.

The inclined side surface 382b of the first color filter pattern 382 has a first angle θ with respect to the first protective layer 374 or the substrate 302.

The first angle θ between the inclined side surface 382b of the first color filter pattern 382 and at least one of the first protective layer 374 or the substrate 302 may satisfy an Equation (1).

wd≤(T(CF1)/tanθ)≤(w1)/2 Equation (1)

In Equation (1), wd is a difference between a width of the light-shielding bank and a width of the black matrix, T(CF1) is a thickness of the first color filter pattern, θ is angle between the inclined side surface of the first color filter pattern and at least one of the first protective layer (or the substrate), and w1 is a width of the light-shielding bank.

A second protection layer 390 is disposed on the black matrix 376 and the color filter layer 380 and over an entire substrate 302.

Referring to FIG. 6, the first color filter pattern 382 may include an upper surface having a sawtooth shape and an inclined side surface having a concave curved shape.

The display device 300 according to the third implementation of the present disclosure includes the black matrix 376 disposed at a boundary of the pixel region P and the color filter layer 380 corresponding to the pixel region P without a polarization plate so that ambient light reflection and brightness degradation can be minimized.

In addition, since the display device 300 further includes the light-shielding bank 356 surrounding the light emitting diode and disposed at a boundary of the pixel region P, the ambient light reflection can be further decreased, and a leakage current from the first and second TFTs T1 and T2 by the ambient light reflection can be reduced.

Moreover, since the black matrix 376 has a width being smaller than the light-shielding bank 356, a viewing angle decrease by the black matrix 376 can be reduced.

Further, since the color filter layer 380 includes the first color filter pattern 382 having the inclined side surface 382b, the transparent resin pattern 384 corresponding to the inclined side surface 382b and the second color filter pattern 386 covering the transparent resin pattern 384 and the upper surface 382a of the first color filter pattern 382, the ambient light reflection can be further decreased.

Furthermore, since the ambient light through an edge of the first color filter pattern 382 passes through the second color filter pattern 386, an ambient light reflection in adjacent pixel region, which may be occurred in the display device according to the first implementation of the present disclosure, can be reduced.

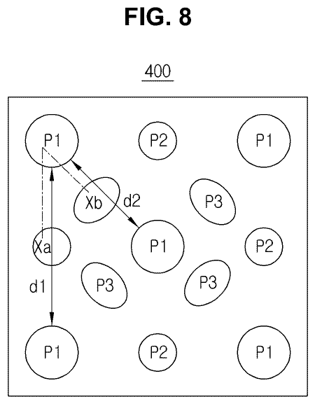

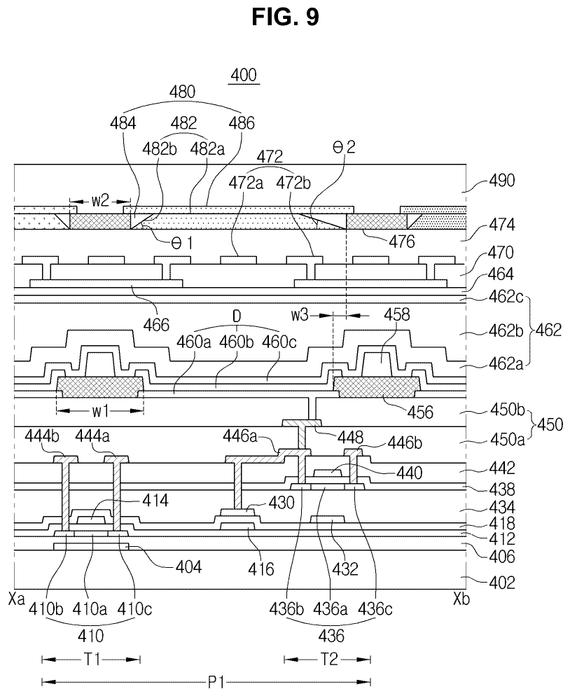

FIG. 8 is a schematic plane view illustrating an organic light emitting display device according to a fourth implementation of the present disclosure, and FIG. 9 is a schematic cross-sectional view taken along the line Xa-Xb in FIG. 8.

As shown in FIG. 8, an organic light emitting display device 400 includes a plurality of first pixel region P1, a second pixel region P2 disposed between adjacent first pixel regions P1 in a first direction and a third pixel region P3 disposed between adjacent first pixel regions P1 in a second direction. The first and second directions cross each other. The second pixel region P2 may be disposed between adjacent third pixel regions P3 in a third direction crossing the first and second directions.

The first pixel region P1 is one of red, green and blue pixel regions. The second pixel region P2 is another one of the red, green and blue pixel regions, and the third pixel region P3 is the other one of the red, green and blue pixel regions.

Adjacent first pixel regions P1 in the first direction has a first distance d1, and adjacent first pixel regions P1 in the second direction has a second distance d2 being smaller than the first distance d1.

Referring to FIG. 9 with FIG. 8, the organic light emitting display device 400 includes a substrate 402 including a plurality of pixel regions P1, P2 and P3, a light emitting diode D corresponding to each of the pixel regions P1, P2 and P3 and disposed on the substrate 402, a light-shielding bank 456 over the substrate 402 and positioned at a boundary of the pixel regions P1, P2 and P3, a black matrix 476 over the light-shielding bank 456 and corresponding to the light-shielding bank 456, and a color filter layer 480 disposed on and corresponding to the light emitting diode D.

The pixel regions P1, P2 and P3 are defined on the substrate 402. The substrate 402 may be a glass substrate or a plastic substrate. In an aspect of the present disclosure, the substrate 402 may have a triple-layered structure including a first polyimide layer, a second polyimide layer and an interlayer inorganic layer between the first and second polyimide layers.

A first light-shielding pattern 404 is disposed on the substrate 402, and a first buffer layer 406 covering the first light-shielding pattern 404 is disposed on the substrate 402.

A first semiconductor layer 410 corresponding to the first light shielding pattern 404 is disposed on the first buffer layer 406. The first semiconductor layer 410 may include one of a poly-semiconductor material, an amorphous semiconductor material and an oxide semiconductor material. When the first light shielding pattern 404 and the first buffer layer 406 are omitted, the first semiconductor layer 410 may be directly disposed on the substrate 402.

In an aspect of the present disclosure, the first semiconductor layer 410 may be formed of a poly-semiconductor material, e.g., polycrystalline silicon. The first semiconductor layer 410 may include a first channel region 410a, a first source region 410b at one side of the first channel region 410a and a first drain region 410c at the other side of the first channel region 410a. Impurities may be dopped into the first source and drain regions 410b and 410c.

A first gate insulating layer 412 covering the first semiconductor layer 410 is disposed on the first buffer layer 406.

A first gate electrode 414 corresponding to the first channel region 410a of the first semiconductor layer 410 is disposed on the first gate insulating layer 412. In addition, a first capacitor electrode 416, which is spaced apart from the first gate electrode 414, is disposed on the first gate insulating layer 412.

A first interlayer insulating layer 418 covering the first gate electrode 414 and the first capacitor electrode 416 is disposed on the first gate insulating layer 412.

A second capacitor electrode 430 corresponding to the first capacitor electrode 416 and a second light shielding pattern 432 spaced apart from the second capacitor electrode 430 are disposed on the first interlayer insulating layer 418.

A second interlayer insulating layer 434 covering the second capacitor electrode 430 and the second light shielding pattern 432 is disposed on the first interlayer insulating layer 418.

A second semiconductor layer 436 corresponding to the second light shielding pattern 432 is disposed on the second interlayer insulating layer 434. The second semiconductor layer 436 may include one of a poly-semiconductor material, an amorphous semiconductor material and an oxide semiconductor material.

In an aspect of the present disclosure, the second semiconductor layer 436 may be formed of an oxide semiconductor material, e.g., indium-gallium-zinc oxide (IGZO), zinc oxide (ZnO), tin oxide (SnO2), copper oxide (Cu2O), nickel oxide (NiO), indium-tin-zinc oxide (ITZO) or indium-aluminum-zinc oxide (IAZO).

The second semiconductor layer 436 may include a second channel region 436a, a second source region 436b at one side of the second channel region 436a and a second drain region 436c at the other side of the second channel region 436a. Impurities may be dopped into the second source and drain regions 436b and 436c.

A second gate insulating layer 438 covering the second semiconductor layer 436 is disposed on the second interlayer insulating layer 434.

A second gate electrode 440 corresponding to the second channel region 436a of the second semiconductor layer 436 is disposed on the second gate insulating layer 436.

A third interlayer insulating layer 442 covering the second gate electrode 440 is disposed on the second gate insulating layer 438.

A first source electrode 444a, a first drain electrode 444b, a second source electrode 446a and a second drain electrode 446b are disposed on the third interlayer insulating layer 442.

The first source electrode 444a and the first drain electrode 444b are respectively connected to the first source region 410b and the first drain region 410c via contact holes through the third interlayer insulating layer 442, the second gate insulating layer 438, the second interlayer insulating layer 434, the first interlayer insulating layer 418 and the first gate insulating layer 412. The first source electrode 444a is connected to the first capacitor electrode 416 via a contact hole through the third interlayer insulating layer 442, the second gate insulating layer 438, the second interlayer insulating layer 434 and the first interlayer insulating layer 418.

The second source electrode 446a and the second drain electrode 446b are respectively connected to the second source region 436b and the second drain region 436c via contact holes through the third interlayer insulating layer 442 and the second gate insulating layer 438. The second source electrode 446a is connected to the second capacitor electrode 430 via a contact hole through the third interlayer insulating layer 442, the second gate insulating layer 438 and the second interlayer insulating layer 434.

The first semiconductor layer 410, the first gate electrode 414, the first source electrode 444a and the first drain electrode 444b constitute a first TFT T1, and the second semiconductor layer 436, the second gate electrode 440, the second source electrode 446a and the second drain electrode 446b constitute a second TFT T2.

A planarization layer 450 covering the first source and drain electrodes 444a and 444b and the second source and drain electrodes 446a and 446b is disposed on the third interlayer insulating layer 442. The planarization layer 450 may be formed of an organic insulating material, e.g., photo-acryl or BCB.

The planarization layer 450 may include a first planarization layer 450a on the first source and drain electrodes 444a and 444b and the second source and drain electrodes 446a and 446b and a second planarization layer 450b on the first planarization layer 450a.

A connection electrode 448 corresponding to the second source electrode 446a is disposed on the first planarization layer 450a. The connection electrode 448 may connected to the second source electrode 446a through a contact hole in the first planarization layer 450a.

The second planarization layer 450b is disposed on the first planarization layer 450a to cover the connection electrode 448, and a first electrode 460a is disposed on the second planarization layer 450b. The first electrode 460a corresponds to the connection electrode 448 and is connected to the connection electrode 448 through a contact hole in the second planarization layer 450b.

For example, the first electrode 460a is separately formed in each pixel region P. The first electrode 460a may be an anode and may include a transparent conductive oxide (TCO) layer, which is formed of a conductive material, e.g., a transparent conductive oxide material, having a relatively high work function, and a reflective layer.

For example, the transparent conductive oxide material may include at least one of indium-tin-oxide (ITO), indium-zinc-oxide (IZO), indium-tin-zinc oxide (ITZO), tin oxide (SnO), zinc oxide (ZnO), indium-copper-oxide (ICO) and aluminum-zinc-oxide (Al:ZnO, AZO), and the reflective layer may include at least one of silver (Ag), an alloy of Ag and one of palladium (Pd), Cu, In and Nd and aluminum-palladium-copper alloy (APC). For example, the first electrode 460a may have a double-layered structure of Ag/ITO or APC/ITO or a triple-layered structure of ITO/Ag/ITO or ITO/APC/ITO.

A light-shielding bank 456 is formed on the second planarization layer 450b at a boundary of the pixel region P. The light-shielding bank 456 covers an edge of the first electrode 460a and has a first opening to expose a center of the first electrode 460a. The light-shielding bank 456 may extend into a portion of the non-display area NDA. The light-shielding bank 456 may include an organic insulating material and a light-absorbing particle, e.g., a black particle, to have a light-absorbing property. For example, the organic insulating material may be at least one of photo-acryl, benzocyclobutene (BCB) and polyimide, and the light-absorbing particle may be at least one of carbon black, carbon nano-tube and graphene.

The light-shielding bank 456 may have an optical density (OD) being 1.2 or more. The light-shielding bank 456 can absorb most of the light and transmit some of the light.

A spacer 458 is disposed on the light-shielding bank 456. For example, the spacer 458 may be formed of an organic insulating material, e.g., photo-acryl or BCB, and have a single-layered structure or a multi-layered structure. The spacer 458 may be omitted.

An organic light emitting layer 460b covering the first electrode 460a, the light-shielding bank 456 and the spacer 458 is disposed. The organic light emitting layer 460b contacts the first electrode 460a in the first opening of the light-shielding bank 456. Namely, the organic light emitting layer 460b may be formed to contact an upper surface of the first electrode 460a, a side surface and an upper surface of the light-shielding bank 456 and a side surface and an upper surface of the spacer 458.

For example, the organic light emitting layer 460b may include an EML including a host and a dopant. In addition, the organic light emitting layer 460b may further include at least one of an HIL, an HTL, an EBL, an HBL, an ETL and an EIL to have a multi-layered structure.

A second electrode 460c is formed over the substrate 402 where the organic emitting layer 460b is formed. The second electrode 460c covers an entire surface of the display area. The second electrode 460c may be formed of at least one of ITO, IZO, Al, Ag, Cu, Pb, magnesium (Mg), Mo, Ti, or an alloy thereof, and have a single-layered structure or a multi-layered structure. The second electrode 460c may have a thin profile (small thickness) to provide a light transmittance property (or a semi-transmittance property).

The first electrode 460a, the organic light emitting layer 460b and the second electrode 460c constitute a light emitting diode D. The light emitting diode D may emit the red, green and blue light in the red, green and blue pixel region, respectively.

In the organic light emitting display device 400, the light from the organic light emitting layer 460b passes through the second electrode 460c to display an image. Namely, the organic light emitting display device 400 of the present disclosure is a top-emission type display device.

An encapsulation layer (or encapsulation film) 462 is formed on the second electrode 460c to prevent penetration of moisture into the light emitting diode D. The encapsulation layer 462 may cover an entire substrate 402. The encapsulation layer 462 includes a first inorganic insulating layer 462a, an organic insulating layer 462b and a second inorganic insulating layer 462c sequentially stacked, but it is not limited thereto.

A second buffer layer 464 is disposed on the encapsulating layer 462. The second buffer layer 464 may serve to block external moisture and/or oxygen.

A bridge pattern 466 is disposed on the second buffer layer 464, and a fourth interlayer insulating layer 470 is disposed on the bridge pattern 466 and over an entire substrate 402.

A touch electrode 472 is disposed on the fourth interlayer insulating layer 470. The touch electrode 472 may include a plurality of first touch electrodes 472a and a plurality of second touch electrodes 472b. The first touch electrodes 472a are spaced part from each other, and the second touch electrodes 472b are disposed between the first touch electrodes. The second touch electrodes 472b are connected to each other through the bridge pattern 466 on the fourth interlayer insulating layer 470.

A first protection layer 474 is disposed on the first and second touch electrodes 472a and 472b.

A black matrix 476 is disposed on the first protection layer 474. The black matrix 476 is positioned at a boundary of the pixel region P and has a second opening in correspondence to the light emitting diode D. Namely, the second opening of the black matrix 476 corresponds to the first opening of the light-shielding bank 456.

The second opening of the black matrix 476 has an area being greater than the first opening of the light-shielding bank 456. The light-shielding bank 456 has a first width w1, and the black matrix 476 has a second width w2 being smaller than the first width w1. When an area of the second opening of the black matrix 476 is equal to or smaller than that of the first opening of the light-shielding bank 456, a viewing angle of the organic light emitting display device 400 may be decreased.

For example, the black matrix 476 may completely overlap the light-shielding bank 456, and an end of the light-shielding bank 456 protrudes from an end of the black matrix 476 by a third width w3. In other words, an end of the light-shielding bank 456 with the third width w3 is not covered by the black matrix 476.

The color filter layer 480 corresponding to the second opening of the black matrix 476 is disposed on the first protection layer 474. The color filter layer 480 may include a red color filter corresponding to the red pixel region, a green color filter corresponding to the green pixel region and a blue color filter corresponding to the blue pixel region.

The color filter layer 480 includes a first color filter pattern 482 having an upper surface 482a and an inclined side surface 482b, a transparent resin pattern 484 corresponding to the inclined side surface 482b and a second color filter pattern 486 covering the transparent resin pattern 484 and the upper surface 482a of the first color filter pattern 482.

The transparent resin pattern 484 fills a space between the black matrix 476 and the inclined side surface 482b of the first color filter pattern 482. The second color filter pattern 486 covers the first color filter pattern 482 and the transparent resin pattern 484 so that the color filter layer 480 provides a flat top surface.

Namely, the first and second color filter patterns 482 and 486 are spaced apart from each other at an edge of the pixel region P with the transparent resin pattern 484 therebetween, and contact each other at a center of the pixel region P. In another implementation of the present disclosure, the transparent resin pattern 484 may cover both the upper surface 482a and the inclined side surface 482b, and the first and second color filter patterns 482 and 486 may be spaced apart from each other at both an edge and a center of the pixel region P with the transparent resin pattern 484 therebetween.

The first color filter pattern 482 has a first thickness, and the second color filter pattern 486 has a second thickness being equal to or smaller than the first thickness. In an aspect of the present disclosure, a thickness of the second color filter pattern 486 may be smaller than that of the first color filter pattern 482.

The first color filter pattern 482 has a first refractive index, the second color filter pattern 486 has a second refractive index being greater than the first refractive index, and the transparent resin pattern 484 has a third refractive index being equal to or smaller than the second refractive index.

For example, the first refractive index may be in a range of 1.3 to 1.5, and each of the second refractive index and the third refractive index may be in a range of 1.5 to 1.8. In an aspect of the present disclosure, the first refractive index may be in a range of 1.34 to 1.5, and each of the second refractive index and the third refractive index may be in a range of 1.5 to 1.7. A difference between the first refractive index and the second refractive index may be in a range of 0.05 to 0.1, preferably 0.07 to 0.1. A difference between the first refractive index and the third refractive index may be greater than a difference between the second refractive index and the third refractive index.

The first color filter pattern 482 includes a first organic insulating material and a first color particle. The first organic insulating material may be selected from the group that includes polymethylmethacrylate, polycarbonate, polyacrylate, polyurethane, epoxy, polyester and polyimide, but it is not limited thereto. The first color particle may be a pigment or a dye.

The second color filter pattern 486 includes a second organic insulating material and a second color particle, and the transparent resin pattern 484 includes a third organic insulating material. For example, each of the second and third organic insulating materials may be selected from the group that includes polydimethylsiloxane, polysiloxane, polytetrafluoroethylene, fluorinated ethylene propylene and fluorinated polyimide, but it is not limited thereto. In an aspect of the present disclosure, the transparent resin pattern 484 may be formed of the same material as the second color filter pattern 486 without the second color particle.

The second color particle may be a pigment or a dye. The first color particle and the second color particle transmit the light having the same wavelength range and absorb the light having the rest wavelength range. For example, each of the first and second color particles may be a red color particle.

In the first direction, the inclined side surface 482b of the first color filter pattern 482 has a first angle θ1 with respect to the first protective layer 474 (or the substrate 402). In the second direction, the inclined side surface 482b of the first color filter pattern 482 has a second angle θ2 with respect to the first protective layer 474 (or the substrate 402). The second angle θ2 is smaller than the first angle θ1. Namely, the inclined side surface 482b of the first color filter pattern 482 has different angle according to a direction.

In the first direction, where the same color pixel regions are spaced apart from each other by the first distance d1, the inclined side surface 482b of the first color filter pattern 482 has the first angle θ1 with respect to the first protective layer 474 (or the substrate 402). In the second direction, where the same color pixel regions are spaced apart from each other by the second distance d2 being smaller than the first distance d1, the inclined side surface 482b of the first color filter pattern 482 has a second angle θ2, which is smaller than the first angle θ1, with respect to the first protective layer 474 (or the substrate 402).

When an angle of the inclined side surface 482b is increased, a refraction angle of the light through the color filter layer 482 is increased. For example, when an angle of the inclined side surface 482b in the second direction, where a distance between the same color pixel regions is relatively small, is increased, an ambient light, which is incident to one pixel region and is refracted, may be incident to adjacent pixel region.

When an angle of the inclined side surface 482b is decreased, a refraction angle of the light through the color filter layer 482 is decreased. For example, when an angle of the inclined side surface 482b is relatively small, an ambient light, which is incident to one pixel region and is refracted, may be incident to the one pixel region.

In the organic light emitting display device 400 according to the fourth implementation of the present disclosure, since the first angle θ1 between the inclined side surface 482b and the first protective layer 474 (or the substrate 402) in a direction, where a distance between the same color pixel regions is relatively large, is greater than the second angle θ2 between the inclined side surface 482b and the first protective layer 474 (or the substrate 402) in a direction, where a distance between the same color pixel regions is relatively small, an ambient light reflection can be minimized or reduced.

A second protection layer 490 is disposed on the black matrix 476 and the color filter layer 480 and over an entire substrate 402.

In FIG. 9, the color filter layer 480 has a structure including the first color filter pattern 482, the transparent resin pattern 484 and the second color filter pattern 486. Alternatively, as explained with FIG. 5, the color filter layer 480 may have a structure including the first color filter pattern 482 and the second color filter pattern 486 without the transparent resin pattern 484.

The display device 400 according to the fourth implementation of the present disclosure includes the black matrix 476 disposed at a boundary of the pixel region P and the color filter layer 480 corresponding to the pixel region P without a polarization plate so that ambient light reflection and brightness degradation can be minimized.

In addition, since the display device 400 further includes the light-shielding bank 456 surrounding the light emitting diode and disposed at a boundary of the pixel region P, the ambient light reflection can be further decreased, and a leakage current from the first and second TFTs T1 and T2 by the ambient light reflection can be reduced.

Moreover, since the black matrix 476 has a width being smaller than the light-shielding bank 456, a viewing angle decrease by the black matrix 476 can be reduced.

Further, since the color filter layer 480 includes the first color filter pattern 482 having the inclined side surface 482b, the transparent resin pattern 484 corresponding to the inclined side surface 482b and the second color filter pattern 486 covering the transparent resin pattern 484 and the upper surface 482a of the first color filter pattern 482, the ambient light reflection can be further decreased.

Furthermore, since the ambient light through an edge of the first color filter pattern 482 passes through the second color filter pattern 486, an ambient light reflection in adjacent pixel region, which may be occurred in the display device according to the first implementation of the present disclosure, can be reduced.

Since the first angle θ1 between the inclined side surface 482b and the first protective layer 474 (or the substrate 402) in a direction, where a distance between the same color pixel regions is relatively large, is greater than the second angle θ2 between the inclined side surface 482b and the first protective layer 474 (or the substrate 402) in a direction, where a distance between the same color pixel regions is relatively small, an ambient light reflection can be minimized or reduced.

A shape of the first color filter pattern 482 of the color filter layer 480 is not limited as long as the first color filter pattern 482 has an upper surface 482a and an inclined side surface 482b. For example, referring to FIG. 6, the first color filter pattern 482 may include an upper surface having a sawtooth shape and an inclined side surface having a concave curved shape.

It will be apparent to those skilled in the art that various modifications and variations can be made in the implementations of the present disclosure without departing from the spirit or scope of the present disclosure. Thus, it is intended that the modifications and variations cover this disclosure provided they come within the scope of the appended claims and their equivalents.

What is claimed is:

1. A display device, comprising:
a substrate including a pixel region;
a light emitting diode corresponding to the pixel region and disposed on the substrate;
a light-shielding bank corresponding to a boundary of the pixel region and disposed on the substrate;
a black matrix corresponding to the light-shielding bank and disposed on the light-shielding bank; and
a color filter layer corresponding to the light emitting diode and disposed on the light emitting diode,
wherein the color filter layer includes a first color filter pattern including an inclined side surface and a second color filter pattern on the first color filter pattern, and
wherein the first color filter pattern has a first refractive index, and the second color filter pattern has a second refractive index being greater than the first refractive index.

2. The display device according to claim 1, wherein a difference between the first refractive index and the second refractive index is greater than or equal to 0.7.

3. The display device according to claim 1, wherein the first color filter pattern includes a first organic insulating material and a first color particle, and the second color filter pattern includes a second organic insulating material and a second color particle,
wherein the first organic insulating material is selected from the group that includes polymethylmethacrylate, polycarbonate, polyacrylate, polyurethane, epoxy, polyester and polyimide,
wherein the second organic insulating material is selected from the group that includes polydimethylsiloxane, polysiloxane, polytetrafluoroethylene, fluorinated ethylene propylene and fluorinated polyimide.

4. The display device according to claim 3, wherein an absorption wavelength range of the first color particle is same as an absorption wavelength range of the second color particle.

5. The display device according to claim 1, wherein the light-shielding bank has a first width, and the black matrix has a second width being smaller than the first width.

6. The display device according to claim 1, further comprising:
an insulating layer covering the light emitting diode and the light-shielding bank and disposed under the black matrix and the color filter layer.

7. The display device according to claim 6, wherein the inclined side surface has an angle of 30 to 70 degree with respect to the insulating layer.

8. The display device according to claim 1, wherein the color filter layer further includes a transparent resin pattern between the inclined side surface and the second color filter pattern.

9. The display device according to claim 8, wherein the transparent resin pattern has a third refractive index, and
wherein the third refractive index is greater than the first refractive index and equal to or smaller than the second refractive index.

10. The display device according to claim 9, wherein a difference between the first refractive index and the third refractive index is greater than or equal to 0.7.

11. The display device according to claim 9, wherein the difference between the first refractive index and the third refractive index is greater than a difference between the second refractive index and the third refractive index.

12. The display device according to claim 8, wherein the first color filter pattern includes a first organic insulating material and a first color particle, and the second color filter pattern includes a second organic insulating material and a second color particle,
wherein the transparent resin pattern includes a third organic insulating material,
wherein the first organic insulating material is selected from the group that includes polymethylmethacrylate, polycarbonate, polyacrylate, polyurethane, epoxy, polyester and polyimide,
wherein each of the second and third organic insulating materials is independently selected from the group that includes polydimethylsiloxane, polysiloxane, polytetrafluoroethylene, fluorinated ethylene propylene and fluorinated polyimide.

13. The display device according to claim 1, wherein the inclined side surface has a curved shape.

14. The display device according to claim 1, wherein the pixel region includes a first pixel region, a second pixel region being spaced apart from the first pixel region in a first direction by a first distance and a third pixel region being spaced apart from the first pixel region in a second direction by a second distance,
wherein the first distance is greater than the second distance,
wherein in the color filter layer in the first pixel region, the inclined side surface facing the second pixel region has a first angle with respect to the substrate, and the inclined side surface facing the third pixel region has a second angle with respect to the substrate, and
wherein the first angle is greater than the second angle.

15. The display device according to claim 14, wherein the color filter layer in the first pixel region, the color filter layer in the second pixel region and the color filter layer in the third pixel region are a color filter layer having the same color.

16. The display device according to claim 1, wherein an angle between the inclined side surface and the substrate satisfies an Equation (1):
wd≤(T(CF1)/tanθ)≤(w1)/2, Equation (1)
wherein wd is a difference between a width of the light-shielding bank and a width of the black matrix, and T(CF1) is a thickness of the first color filter pattern,
wherein θ is angle between the inclined side surface and the substrate, and w1 is a width of the light-shielding bank.

17. The display device according to claim 1, wherein the first color filter pattern includes an upper surface having a planar sawtooth shape.

18. The display device according to claim 1, further comprising:
a thin film transistor in the pixel region,
wherein the thin film transistor includes a semiconductor layer of an oxide semiconductor material.

19. The display device according to claim 1, further comprising:
a first thin film transistor including a first semiconductor layer and a second thin film transistor including a second semiconductor layer in the pixel region,
wherein at least one of the first and second semiconductor layers is formed of an oxide semiconductor material.

20. The display device according to claim 1, further comprising:
a first thin film transistor including a first semiconductor layer and a second thin film transistor including a second semiconductor layer in the pixel region,
wherein one of the first and second semiconductor layers is formed of an oxide semiconductor material, and the other one of the first and second semiconductor layers is formed of a poly-semiconductor material.

21. The display device according to claim 1, wherein the display device does not include a polarization plate.
